(19) United States
(12) Patent Application Publication
(10) Pub. No.: US 2026/0013114 A1
(43) Pub. Date: Jan. 8, 2026

(54) SEMICONDUCTOR STRUCTURE AND METHOD OF MANUFACTURING THE SAME

(71) Applicant: NANYA TECHNOLOGY CORPORATION, New Taipei City (TW)

(72) Inventor: Szu-Yao CHANG, New Taipei City (TW)

(21) Appl. No.: 18/762,630

(22) Filed: Jul. 2, 2024

(51) Int. Cl. H10B 12/00

(52) U.S. Cl. CPC H10B 12/373; H10B 12/0383; H10B 12/0385; H10B 12/05; H10B 12/482; H10B 12/488

(57) ABSTRACT

Embodiments of this disclosure provide a semiconductor structure, including a metal layer disposed on a substrate, a first dielectric layer disposed on the metal layer, a second dielectric layer disposed on the first dielectric layer, a first insulating layer disposed on the second dielectric layer, a plurality of capacitors disposed on the metal layer in the first dielectric layer and the second dielectric layer, and a contact disposed on the metal layer in the first dielectric layer, the second dielectric layer and the first insulating layer. A top surface of the contact and a top surface of the first insulating layer are coplanar. Additionally, a method of manufacturing a semiconductor structure is also disclosed in this disclosure.

### BACKGROUND

### Field of Invention

The present disclosure relates to a semiconductor structure and a method of manufacturing the same involving forming a contact over the substrate in one step.

### Description of Related Art

As electronic devices become lighter and thinner, semiconductor devices, such as dynamic random access memory (DRAM) become more highly integrated. Further, the performance of the DRAM is improved via shortening the pitch between the semiconductor structures in the DRAM. In addition to increasing the difficulty of the manufacturing process, the components in the semiconductor structures are also prone to leakage resulting from too close distances because of shrinking the size of the semiconductor structure.

As a result, in the semiconductor manufacturing process, how to reduce the leakage to improve the process yield of the semiconductor structure has become an important issue.

### SUMMARY

Embodiments of this disclosure provide a method of manufacturing a semiconductor structure, including the following steps. A first dielectric layer is deposited over a substrate. A second dielectric layer is deposited on the first dielectric layer. A plurality of capacitors is formed in the first dielectric layer and the second dielectric layer. A first insulating layer is deposited on the second dielectric layer and the plurality of capacitors. A contact opening is formed in the first insulating layer, the second dielectric layer and the first dielectric layer. A contact is formed in the contact opening, wherein a top surface of the contact and a top surface of the first insulating layer are coplanar.

In some embodiments, forming the contact includes the following steps. A first conductive layer is conformally deposited in the contact opening. A second conductive layer is filled on the first conductive layer in the contact opening.

In some embodiments, the method further includes the following steps. A second insulating layer is deposited on the first insulating layer and the contact. A word line opening is formed in the second insulating layer until exposing a top surface of the contact, wherein the word line structure has a protruding portion, the protruding portion protrudes perpendicular to an axis of the contact and away from the capacitors, and the protruding portion has a length from a closet edge of the contact.

In some embodiments, a portion of a bottom surface of the word line structure directly contacts the top surface of the contact.

In some embodiments, the method further includes the following steps. A third insulating layer is deposited on the second insulating layer and the word line structure. A plurality of vertical transistors in the first insulating layer, the word line structure and the third insulating layer, wherein a bottom surface of each of the plurality of vertical transistors contacts a central portion of a top surface of each of the plurality of capacitors, respectively.

In some embodiments, the method further includes the following steps. A plurality of landing pads is formed on the plurality of the vertical transistors in the third insulating layer, respectively, wherein a bottom surface of each of the plurality of landing pads contacts a top surface of each of the plurality of vertical transistors.

In some embodiments, the method further includes the following steps. A plurality of bit line structures is formed on the plurality of landing pads, respectively, wherein a central portion of a bottom surface of each of the plurality of bit line structures contacts a top surface of each of the plurality of landing pads.

In some embodiments, forming the plurality of capacitors includes the following steps. A plurality of capacitor openings is formed in the first dielectric layer and the second dielectric layer. A bottom capacitor plate is conformally deposited in each of the plurality of capacitor openings, wherein the bottom capacitor plate is deposited on an inner surface of each of the first openings in the first dielectric layer without being deposited on an inner surface of each of the first openings in the second dielectric layer. An oxide layer is conformally deposited on the bottom capacitor plate and an inner surface of each of the plurality of capacitor openings in the second dielectric layer. A top capacitor plate is formed on the oxide layer, wherein a top surface of the top capacitor plate is lower than a top surface of the second dielectric layer after depositing the oxide layer. A capacitor conductive layer is formed on the top capacitor plate.

In some embodiments, a width of each the plurality of the capacitor openings in the second dielectric layer is greater than a width of each the plurality of the capacitor openings in the first dielectric layer.

In some embodiments, a top surface of the capacitor conductive layer and the top surface of the second dielectric layer are coplanar.

Embodiments of this disclosure provide a semiconductor structure, including a metal layer disposed on a substrate, a first dielectric layer disposed on the metal layer, a second dielectric layer disposed on the first dielectric layer, a first insulating layer disposed on the second dielectric layer, a plurality of capacitors disposed on the metal layer in the first dielectric layer and the second dielectric layer, and a contact disposed on the metal layer in the first dielectric layer, the second dielectric layer and the first insulating layer. A top surface of the contact and a top surface of the first insulating layer are coplanar.

In some embodiments, the contact includes a first conductive layer disposed on the metal layer and a second conductive layer surrounding a sidewall and a bottom surface of the first conductive layer.

In some embodiments, the semiconductor structure includes a second insulating layer disposed on the first insulating layer and a word line structure disposed on the first insulating layer and the contact. A portion of a bottom surface of the word line structure directly contacts the top surface of the contact.

In some embodiments, the semiconductor structure further includes a third insulating layer on the word line structure and the second insulating layer and a plurality of vertical transistors disposed in the first insulating layer, the word line structure, and the third insulating layer. A top surface of each of the plurality of vertical transistors is lower than a top surface of the third insulating layer.

In some embodiments, a bottom surface of each of the plurality of vertical transistors directly contacts a top surface of each of the plurality of capacitors.

In some embodiments, the semiconductor structure further includes a plurality of landing pads on the plurality of vertical transistors, respectively, in the third insulating layer, wherein a central portion of a bottom surface of each of the plurality of landing pads directly contacts a top surface of each of the vertical transistors.

In some embodiments, a top surface of each of the landing pads and a topmost surface of the third insulating layer are coplanar.

In some embodiments, each of the plurality of landing pads includes a bottom conductive layer disposed on each of the plurality of vertical transistors and a middle conductive layer disposed on the bottom conductive layer. The bottom conductive layer includes a lower portion on the bottom conductive layer and having a lower width, and an upper portion on the lower portion and having an upper width, wherein the lower width is greater than the upper width.

In some embodiments, the semiconductor structure further includes a plurality of bit line structures disposed on the plurality of landing pads, respectively.

In some embodiments, a project area of each of the plurality of bit line structures the substrate partially overlaps a project area of the upper portion of the middle conductive layer on the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. The disclosure can be more fully understood by reading the following detailed description of the embodiment, with reference made to the accompanying drawings as follows.

FIGS. 1 to 2 are views of a method of manufacturing a semiconductor structure during forming a plurality of capacitors according to some embodiments of this disclosure,

FIGS. 3 to 4 are views of a method of manufacturing a semiconductor structure during forming a contact according to some embodiments of this disclosure,

FIG. 5 is a view of a method of manufacturing a semiconductor structure during forming a word line structure according to some embodiments of this disclosure,

FIG. 6 is a view of a method of manufacturing a semiconductor structure during forming vertical transistors according to some embodiments of this disclosure,

FIGS. 7 to 9 are views of a method of manufacturing a semiconductor structure during forming a plurality of landing pads and a plurality of bit line structures according to some embodiments of this disclosure, and

FIG. 10 is an enlarged view based on a dashed block in FIG. 9.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

Further, spatially relative terms, such as “on,” “over,” “under,” “between” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The words “comprise”, “include”, “have”, “contain” and the like used in the present disclosure are open terms, meaning including but not limited to.

In related art, when forming a contact for connecting upper elements and lower element in a semiconductor structure, at least two steps are required. Firstly, a contact is formed in a first dielectric layer after forming capacitors in the first dielectric layer, and then a second dielectric layer is deposited and another contact on the contact is formed in the second dielectric layer. In order to simplify the process for forming the contact and save the use of the photomask, a method of manufacturing the same involving forming a contact over the substrate in one step is provided in embodiments of this disclosure.

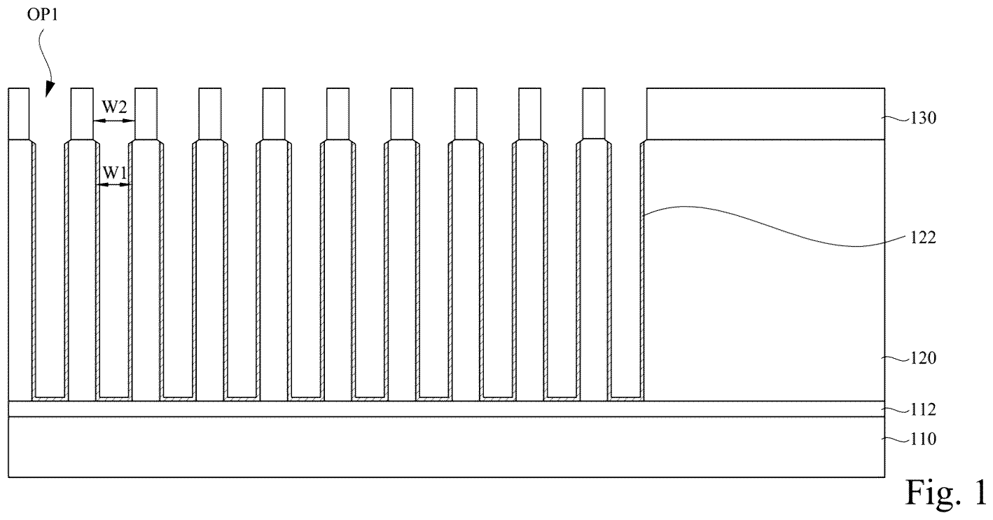

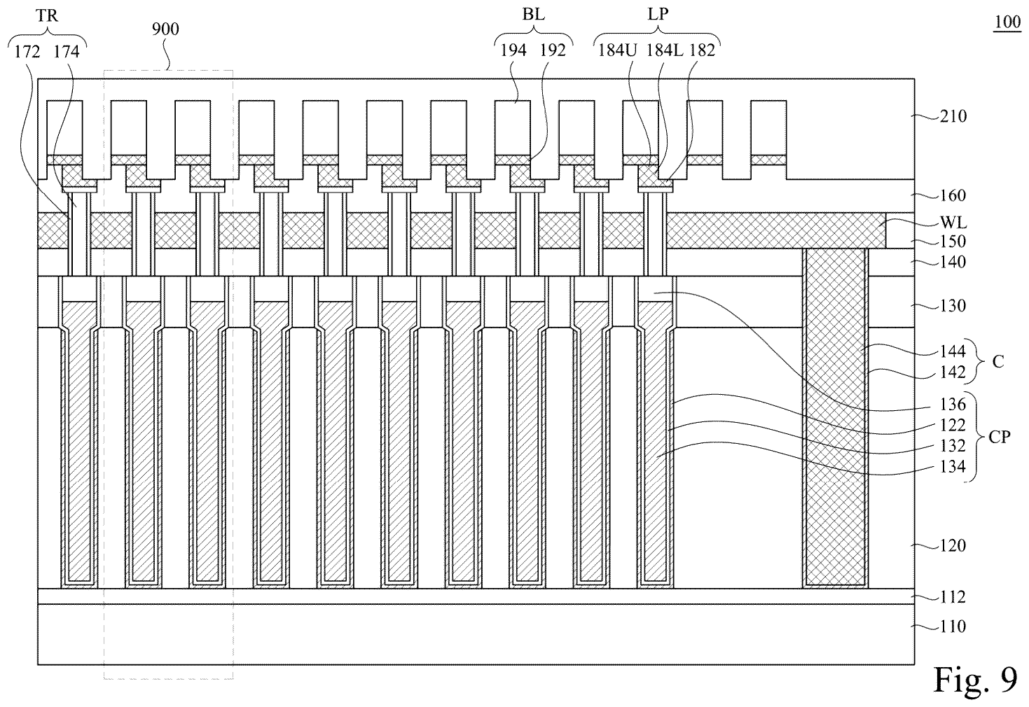

It should be noted that when the following figures, such as FIGS. 1 to 10, are illustrated and described as a series of operations or steps, the description order of these operations or steps should not be limited. For example, some operations or steps may be undertaken in a different order than in the present disclosure, or some operations or steps may occur currently, or some operations may not be used, and/or some operations or steps may be repeated. Moreover, the actual operations or steps of process stages may require additional operations or steps before, during or after forming the semiconductor structure (for example, a semiconductor structure 100 in FIG. 9) to completely form the semiconductor structure 100. Therefore, the present disclosure may briefly illustrate some of these additional operations or steps. Further, unless otherwise stated, the same explanations discussed for the following figures, such as FIGS. 1 to 10, apply directly to the other figures.

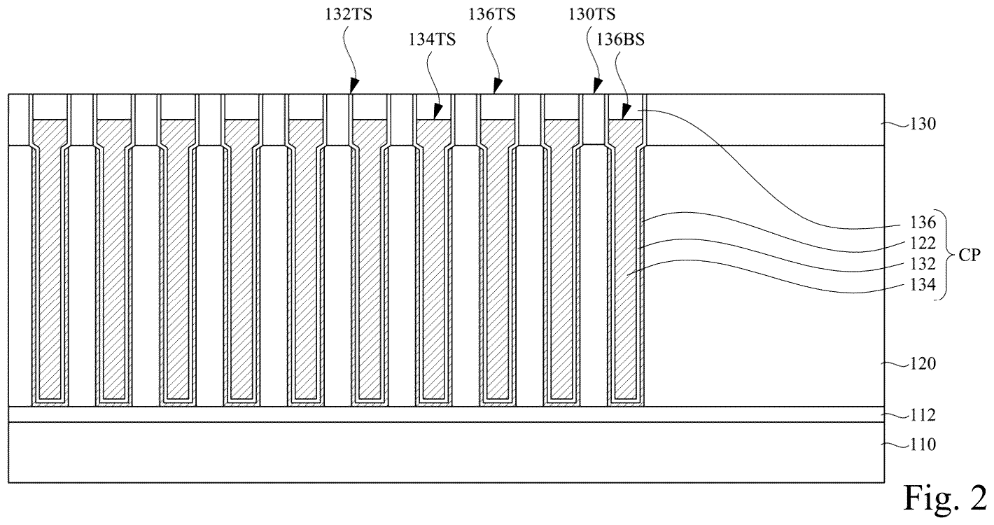

Please refer to FIGS. 1 to 2. FIGS. 1 to 2 are views of a method of manufacturing a semiconductor structure during forming a plurality of capacitors according to some embodiments of this disclosure. In FIG. 1, a substrate 110 with a metal layer 112 on the substrate 110 is provided. In some embodiments, the substrate 110 may include silicon, such as crystalline silicon, polycrystalline silicon, or amorphous silicon. The substrate 110 may include an elemental semiconductor, such as germanium. In some embodiments, the substrate 110 may include alloy semiconductors, such as silicon germanium, silicon germanium carbide, gallium indium phosphide, or other suitable materials. In some embodiments, the substrate 110 may include compound semiconductors, such as silicon carbide (SiC), gallium arsenide (GaAs), indium phosphide (InP), indium arsenide (InAs), or other suitable materials. Moreover, in some embodiments, the substrate 110 can optionally have a semiconductor-on-insulator (SOI) structure. In some embodiments, the metal layer 112 includes tungsten (W), copper (Cu), or other suitable materials.

Next, a first dielectric layer 120 is deposited on the metal layer 112. In some embodiments, the first dielectric layer 120 includes tetraethoxysilane (TEOS). In some embodiments, the first dielectric layer 120 is deposited by chemical vapor deposition (CVD), physical vapor deposition (PVD), or other suitable deposition process. Further, a second dielectric layer 130 is deposited on the first dielectric layer 120. In some embodiments, the second dielectric layer 130 includes nitride, such as SiN. In some embodiments, the second dielectric layer 130 is deposited by CVD, PVD, or other suitable deposition process. In some embodiments, a thickness of the first dielectric layer 120 is greater than a thickness of the second dielectric layer 130.

Next, a plurality of first openings (also called capacitor openings) OP1 is formed in the first dielectric layer 120 and the second dielectric layer 130 until exposing top surfaces of the metal layer 112. In some embodiments, a width W1 of the first openings OP1 in the second dielectric layer 130 is greater than a width W2 of the first openings OP1 in the first dielectric layer 120. A bottom capacitor plate 122 is conformally deposited in each of the first openings OP1 after forming the first openings OP1. Moreover, the bottom capacitor plate 122 is deposited on an inner surface of each of the first openings OP1 in the first dielectric layer 120 without being deposited on an inner surface of each of the first openings OP1 in the second dielectric layer 130. In some embodiments, the bottom capacitor plate 122 includes TiN or other suitable conductive materials.

In FIG. 2, an oxide layer 132 is conformally deposited on the bottom capacitor plate 122 and an inner surface of each of the first openings OP1 in the second dielectric layer 130. In some embodiments, the oxide layer 132 includes oxide, such as ZrO₂. In some embodiments, the oxide layer 132 is deposited by CVD, PVD, or other suitable deposition process. Next, a top surface 134TS of the top capacitor plate 134 and a top surface 132TS of the oxide layer 132 are not coplanar. Specifically, the top surface 134TS of the top capacitor plate 134 is higher than the top surface 120TS of the first dielectric layer 120, and the top surface 134TS of the top capacitor plate 134 is lower than the top surface 130TS of the second dielectric layer 130. In some embodiments, the top capacitor plate 134 includes TiN or other suitable conductive materials. A capacitor conductive layer 136 is formed on the top capacitor plate 134, and a bottom surface 136BS of the capacitor conductive layer 136 directly contacts the top surface 134TS of the top capacitor plate 134. Moreover, a sidewall of the capacitor conductive layer 136 is surrounded by the oxide layer 132. A top surface 132TS of the oxide layer 132 and the top surface 130TS of the second dielectric layer 130 are coplanar. In some embodiments, the capacitor conductive layer 136 includes indium tin oxides (ITO). Consequently, each of the capacitors CP is formed after forming the capacitor conductive layer 136.

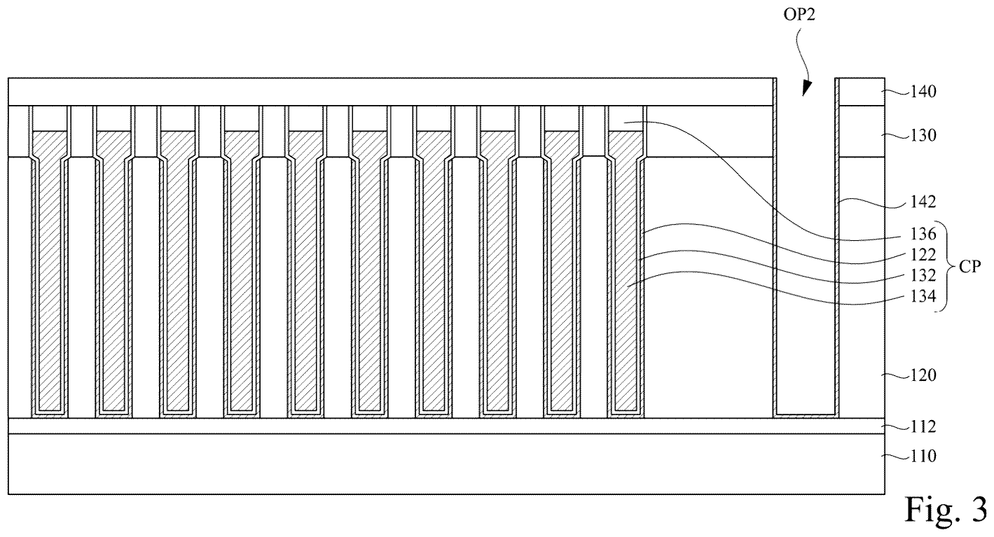

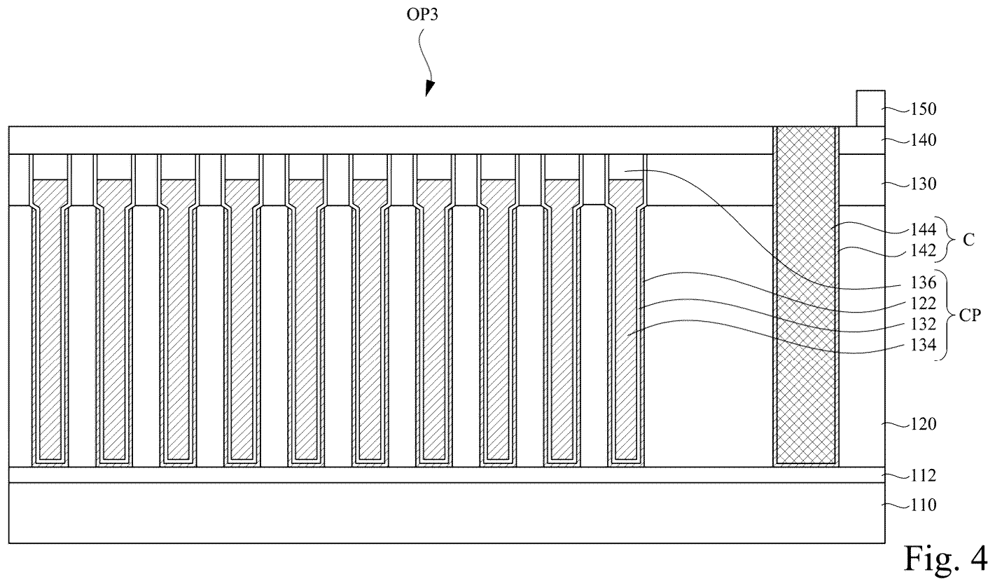

Please refer to FIGS. 3 to 4. FIGS. 3 to 4 are views of a method of manufacturing a semiconductor structure during forming a contact according to some embodiments of this disclosure. In FIG. 3, a first insulating layer 140 is deposited on the second dielectric layer 130 and the capacitors CP after forming the capacitors CP. In some embodiments, the first insulating layer 140 includes oxide, such as SiO₂. Subsequently, a second opening (also called a contact opening) OP2 is formed in the first insulating layer 140, the second dielectric layer 130 and the first dielectric layer 120 until exposing a portion of the top surface of the metal layer 112. In some embodiments, the second opening OP2 is formed by a reactive ion etching (RIE) process. Next, a first conductive layer 142 is conformally deposited in the second opening OP2. In some embodiments, the first conductive layer 142 includes TiN or other suitable conductive materials.

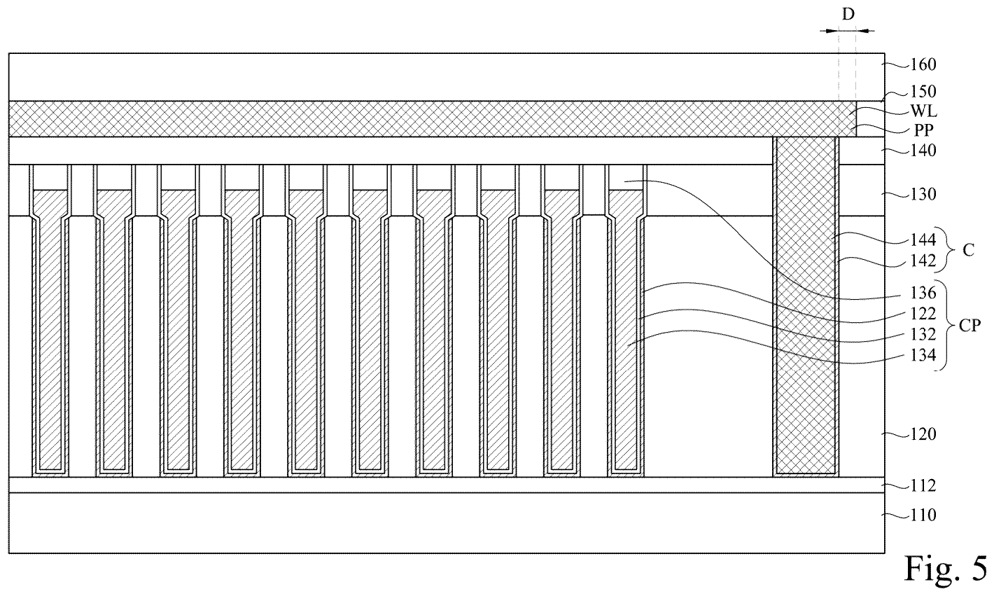

In FIG. 4, a second conductive layer 144 is filled on the first conductive layer 142 in the second opening OP2, and the excessive second conductive layer 144 is removed by a planarization process to make a top surface 144TS of the second conductive layer 144 and a top surface 140 TS of the first insulating layer 140 coplanar. Moreover, a contact C including the first conductive layer 142 and the second conductive layer 144 on the first conductive layer 142 is formed. In some embodiments, the second conductive layer 144 includes W, Cu, or other suitable materials. In some embodiments, the second conductive layer 144 is filled by CVD, PVD, or other suitable deposition process. In some embodiments, the planarization process includes chemical mechanical polishing (CMP). Additionally, a top surface of the contact C and a top surface of the first insulating layer 140 are coplanar. The contact C for connecting the metal layer 112 and a word line structure WL (as shown in FIG. 5 later) may be formed in one step. In this way, the process for forming the contact C may be simplified and the use of the photomask may be saved.

Moreover, in FIG. 4, a second insulating layer 150 is deposited on the first insulating layer 140 and the contact C after forming the contact C. In some embodiments, the second insulating layer 150 includes nitride, oxide, or other suitable materials, such as SiO₂. Subsequently, a third opening (also called a word line opening) OP3 is formed in the second insulating layer 150 until exposing the top surface of the contact C and portions of the top surface of the first insulating layer 140.

Please refer to FIG. 5. FIG. 5 is a view of a method of manufacturing a semiconductor structure during forming a word line structure according to some embodiments of this disclosure. A word line structure WL is formed in the third opening OP3, and a top surface of the word line structure WL and a top surface of the word line structure WL are coplanar. In addition, a portion of a bottom surface of the word line structure WL directly contacts the top surface of the contact C. In some embodiments, the word line structure WL includes W, Cu, or other suitable materials. In some embodiments, the word line structure WL is formed by CVD, PVD, or other suitable deposition process. In some embodiments, forming the word line structure WL includes a planarization process, such as CMP. In some embodiments, the word line structure WL has a protruding portion PP protruding perpendicular to an axis of the contact C and away from the capacitors CP, and the protruding portion PP has a length D from a closet edge of the contact C to an edge of the protruding portion PP. That is, in some embodiments, the edge of the word line structure WL and the edge of the contact C closest to the edge of word line structure WL are not flush. Moreover, a top surface of each of the capacitors CP is lower than the top surface of the word line structure WL. Subsequently, a third insulating layer 160 is deposited on the second insulating layer 150 and the word line structure WL. In some embodiments, the third insulating layer 160 includes nitride, oxide, or other suitable materials, such as SiO₂. Moreover, compared with an interface between another contact and the contact in related art, a resistance-capacitance (RC) value may be reduced due to the contact C is formed in one step in the embodiments of this disclosure.

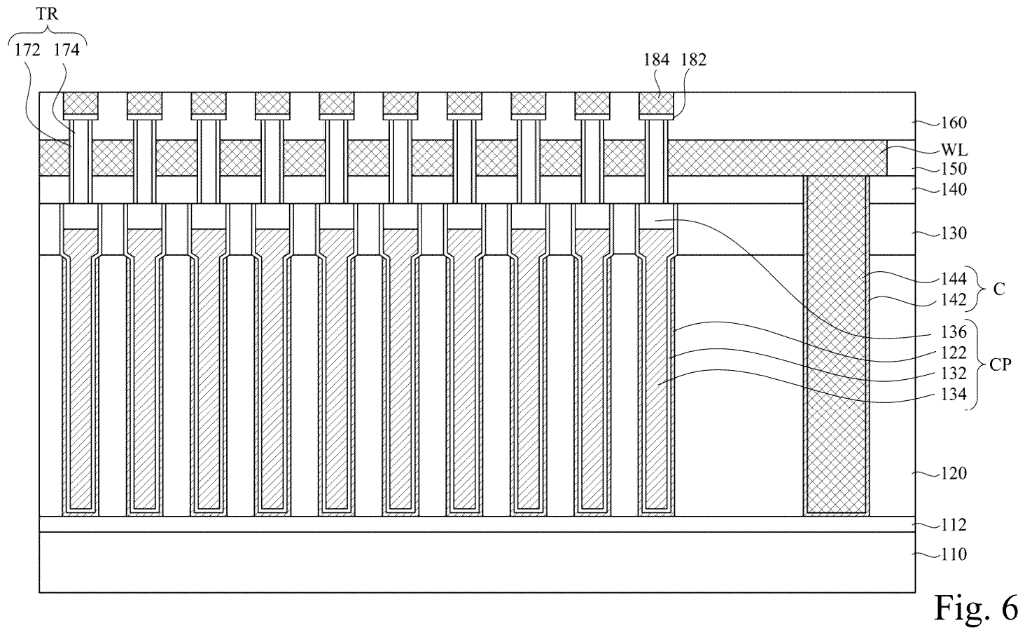

Please refer to FIG. 6. FIG. 6 is a view of a method of manufacturing a semiconductor structure during forming vertical transistors according to some embodiments of this disclosure. A plurality of vertical transistors TR are formed in the first insulating layer 140, the second insulating layer 150 and the third insulating layer 160. Specifically, a plurality of openings (not shown) are formed on the in the first insulating layer 140, the word line structure WL and the third insulating layer 160. Subsequently, a gate oxide layer 172 is formed on an inner surface of each of the openings, and a gate conductive layer 174 is formed in each of the openings to form each of the vertical transistors TR. The gate conductive layer 174 is surrounded by the gate oxide layer 172. In some embodiments, the gate conductive layer 174 includes a conductive material, such as indium gallium zinc oxide (IGZO). Moreover, a bottom surface of each of the vertical transistors TR directly contacts a central portion of a top surface 136TS (as shown in FIG. 2) of the capacitor conductive layer 136, so that each of the vertical transistors TR may be electrically connected to each of the capacitors CP.

Further, a bottom conductive layer 182 is formed on the each of the vertical transistors TR, and a middle conductive layer 184 is formed on the bottom conductive layer 182. Therefore, the bottom conductive layer 182 and the middle conductive layer 184 may be electrically connected to each of the vertical transistors TR. In some embodiments, the bottom conductive layer 182 includes ITO. In some embodiments, the middle conductive layer 184 includes W, Cu, or other suitable conductive materials.

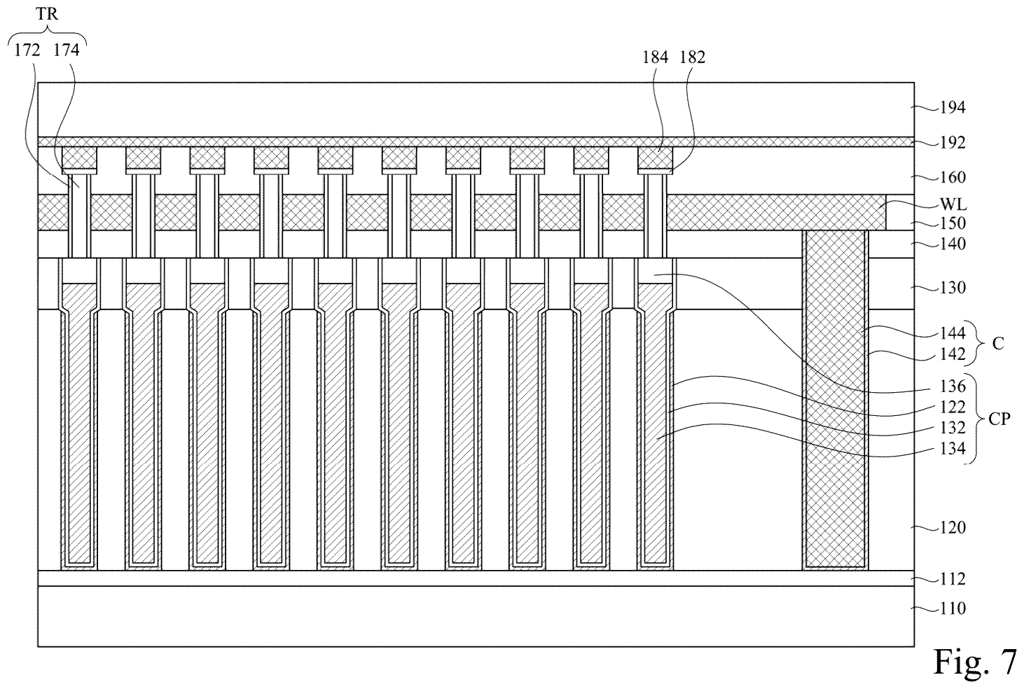

Please refer to FIGS. 7 to 9. FIGS. 7 to 9 are views of a method of manufacturing a semiconductor structure during forming a plurality of landing pads and a plurality of bit line structures according to some embodiments of this disclosure. In FIG. 7, an upper conductive layer 192 is formed on the middle conductive layer 184 and the third insulating layer 160. Next, a third dielectric layer 194 is formed on the upper conductive layer 192. In some embodiments, a thickness of the third dielectric layer 194 is greater than a thickness of the upper conductive layer 192. In some embodiments, the upper conductive layer 192 includes W, Cu, or other suitable conductive materials. In some embodiments, the third dielectric layer 194 includes nitride, oxide, or other suitable materials.

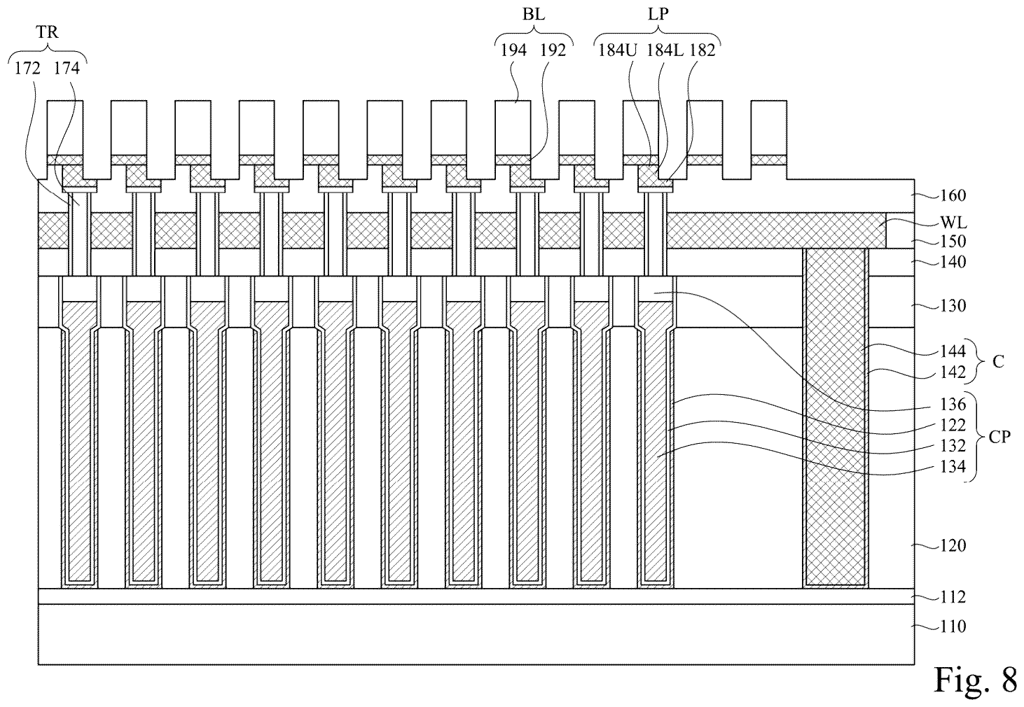

In FIG. 8, a plurality of landing pads LP and a plurality of bit line structures BL are formed over the word line structure WL. Specifically, a lithography process is performed on the third dielectric layer 194, the upper conductive layer 192 and the middle conductive layer 184 (such as in FIG. 7) to remove portions of the third dielectric layer 194, the upper conductive layer 192 and the middle conductive layer 184. After removing the portions of the middle conductive layer 184, a lower middle conductive layer 184L and an upper middle conductive layer 184U on the lower middle conductive layer 184L are formed. After removing the portions of the third dielectric layer 194, the upper conductive layer 192 and the middle conductive layer 184 (such as in FIG. 7), each of the landing pads LP including the bottom conductive layer 182, the lower middle conductive layer 184L and the upper middle conductive layer 184U is formed on the each of the vertical transistors TR. Additionally, a central portion of a bottom surface of the landing pads LP, specifically, a bottom surface of the bottom conductive layer 182, directly contacts a top surface of each of the vertical transistors TR, so that each of the landing pads LP may be electrically connected to the each of the vertical transistors TR. Moreover, compared with an interference between the another contact, the contact and word line structure in the related art, a resistance-capacitance (RC) value of the semiconductor structure 100 (as shown in FIG. 9) may be reduced due to the contact C is formed in one step in the embodiments of this disclosure.

Additionally, after removing the portions of the third dielectric layer 194, the upper conductive layer 192 and the middle conductive layer 184 (such as in FIG. 7), each of the bit line structures BL including the upper conductive layer 192 and the third dielectric layer 194 on the upper conductive layer 192 is formed on each of the landing pads LP. A portion of a bottom surface of each of the bit line structures BL directly contacts a top surface of each of the landing pads LP (specifically, a top surface of the upper middle conductive layer 184U), so that each of the bit line structures BL may be electrically connected to each of the landing pads LP. Subsequently, in FIG. 9, a fourth dielectric layer 210 is deposited on the third insulating layer 160, each of the landing pads LP and each of the bit line structures BL to completely cover LP and BL for protecting LP and BL before subsequent processes. Moreover, the subsequent processes are not the focus in this disclosure, so it will not be described in detail here.

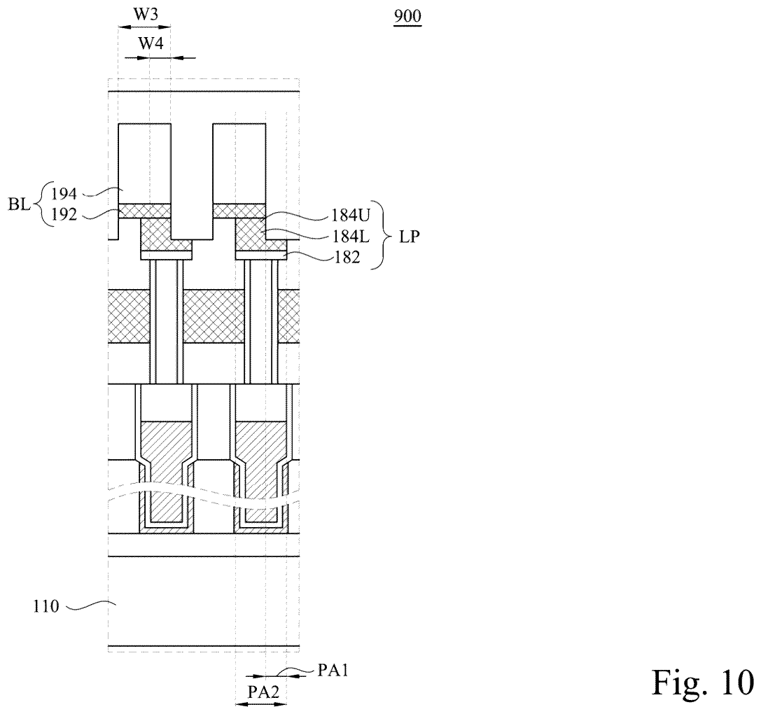

Embodiments of this disclosure also provide a semiconductor structure, as shown in FIGS. 9 and 10. FIG. 10 is an enlarged view based on a dashed block 900 in FIG. 9. In FIG. 9, the semiconductor structure 100 includes a metal layer 112 disposed on a substrate 110, a first dielectric layer 120 disposed on the metal layer 112, a second dielectric layer 130 disposed on the first dielectric layer 120, a first insulating layer 140 disposed on the second dielectric layer 130, a plurality of capacitors CP disposed on the metal layer 112 in the first dielectric layer 120 and the second dielectric layer 130, and a contact C disposed on the metal layer 112 in the first dielectric layer, the second dielectric layer 130 and the first insulating layer 140. A top surface of the contact C and a top surface of the first insulating layer 140 are coplanar.

In some embodiments, the contact C includes a first conductive layer 142 disposed on the metal layer 112 and a second conductive layer 144 surrounding a sidewall and a bottom surface of the first conductive layer 142. Moreover, a bottom surface of the first conductive layer 142 directly contacts a portion of a top surface of the metal layer 112.

In some embodiments, the semiconductor structure 100 also includes a second insulating layer 150 disposed on the first insulating layer 140, and a word line structure WL disposed on the first insulating layer 140 and the contact C. Additionally, a portion of a bottom surface of the word line structure WL directly contacts the top surface of the contact C. In some embodiments, the edge of the word line structure WL and the edge of the contact C closest to the edge of word line structure WL are not flush. In some embodiments, the semiconductor structure 100 also includes a third insulating layer 160 disposed on the word line structure WL and the second insulating layer 150, a plurality of vertical transistors TR disposed in the first insulating layer 140, the word line structure WL, and the third insulating layer 160. Moreover, a top surface of each of the plurality of vertical transistors TR is lower than a top surface of the third insulating layer 160. In some embodiments, a bottom surface of each of the plurality of vertical transistors TR directly contacts a central portion of a top surface of each of the plurality of capacitors CP.

In some embodiments, the semiconductor structure 100 further includes a plurality of landing pads LP, and each of the landing pads LP is disposed on each of the vertical transistors TR in the third insulating layer 160. Moreover, each of the landing pads LP includes a bottom conductive layer 182 disposed on each of the vertical transistors TR and a middle conductive layer 184 disposed on the bottom conductive layer 182. The middle conductive layer 184 includes a lower portion 184L on the bottom conductive layer 182 and having a lower width and an upper portion 184U on the lower portion 184L and having an upper width. Further, the lower width is greater than the upper width. Additionally, a central portion of a bottom surface of each of the plurality of landing pads LP directly contacts a top surface of each of the vertical transistors TR.

In some embodiments, the semiconductor structure also includes a plurality of bit line structures BL, and each of the bit line structures BL is disposed on the plurality of landing pads LP, respectively. As shown in FIG. 10, in a project area PA1 of each of the plurality of bit line structures BL based on the substrate 110 partially overlaps a project area PA2 of the upper portion of the middle conductive layer 184 based on the substrate 110. In some embodiments, a width W3 of each of the bit line structures BL is greater than a width W4 of the upper portion 184U of each of the landing pads LP. It is worth to mention that since some features of various elements in semiconductor structure, such as the metal layer 112, the contact C, each of the capacitors CP, each of the vertical transistors TR and each of the landing pads LP, have been described above, here will not repeat again.

As stated as above, the embodiments of this disclosure provide the contact formed in one step. In this way, it is possible to simplify the process and save the use of the photomask. Additionally, RC value of the semiconductor structure may also be reduced due to the absence of interference from another contact on the contact.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method of manufacturing a semiconductor structure, comprising:
depositing a first dielectric layer over a substrate;
depositing a second dielectric layer on the first dielectric layer;
forming a plurality of capacitors in the first dielectric layer and the second dielectric layer;
depositing a first insulating layer on the second dielectric layer and the plurality of capacitors;
forming a contact opening in the first insulating layer, the second dielectric layer and the first dielectric layer; and
forming a contact in the contact opening, wherein a top surface of the contact and a top surface of the first insulating layer are coplanar.

2. The method of claim 1, wherein forming the contact comprises:
conformally depositing a first conductive layer in the contact opening; and
filling a second conductive layer on the first conductive layer in the contact opening.

3. The method of claim 1, further comprising:
depositing a second insulating layer on the first insulating layer and the contact;
forming a word line opening in the second insulating layer until exposing a top surface of the contact; and
forming a word line structure in the word line opening, wherein the word line structure has a protruding portion, the protruding portion protrudes perpendicular to an axis of the contact and away from the capacitors, and the protruding portion has a length from a closet edge of the contact.

4. The method of claim 3, wherein a portion of a bottom surface of the word line structure directly contacts the top surface of the contact.

5. The method of claim 3, further comprising:
depositing a third insulating layer on the second insulating layer and the word line structure; and
forming a plurality of vertical transistors in the first insulating layer, the word line structure and the third insulating layer, wherein a bottom surface of each of the plurality of vertical transistors contacts a central portion of a top surface of each of the plurality of capacitors, respectively.

6. The method of claim 5, further comprising:
forming a plurality of landing pads on the plurality of the vertical transistors in the third insulating layer, respectively, wherein a bottom surface of each of the plurality of landing pads contacts a top surface of each of the plurality of vertical transistors.

7. The method of claim 6, further comprising:
forming a plurality of bit line structures on the plurality of landing pads, respectively, wherein a central portion of a bottom surface of each of the plurality of bit line structures contacts a top surface of each of the plurality of landing pads.

8. The method of claim 1, wherein forming the plurality of capacitors comprises:
forming a plurality of capacitor openings in the first dielectric layer and the second dielectric layer;
conformally depositing a bottom capacitor plate in each of the plurality of capacitor openings, wherein the bottom capacitor plate is deposited on an inner surface of each of the first openings in the first dielectric layer without being deposited on an inner surface of each of the first openings in the second dielectric layer;
conformally depositing an oxide layer on the bottom capacitor plate and an inner surface of each of the plurality of capacitor openings in the second dielectric layer;
forming a top capacitor plate on the oxide layer, wherein a top surface of the top capacitor plate is lower than a top surface of the second dielectric layer after depositing the oxide layer; and
forming a capacitor conductive layer on the top capacitor plate.

9. The method of claim 8, wherein a width of each the plurality of the capacitor openings in the second dielectric layer is greater than a width of each the plurality of the capacitor openings in the first dielectric layer.

10. The method of claim 8, wherein a top surface of the capacitor conductive layer and the top surface of the second dielectric layer are coplanar.

11. A semiconductor structure, comprising:
a metal layer disposed on a substrate;
a first dielectric layer disposed on the metal layer;
a second dielectric layer disposed on the first dielectric layer;
a first insulating layer disposed on the second dielectric layer;
a plurality of capacitors disposed on the metal layer in the first dielectric layer and the second dielectric layer; and
a contact disposed on the metal layer in the first dielectric layer, the second dielectric layer and the first insulating layer, wherein a top surface of the contact and a top surface of the first insulating layer are coplanar.

12. The semiconductor structure of claim 11, wherein the contact comprises:
a first conductive layer disposed on the metal layer; and
a second conductive layer surrounding a sidewall and a bottom surface of the first conductive layer.

13. The semiconductor structure of claim 11, further comprising:
a second insulating layer disposed on the first insulating layer; and
a word line structure disposed on the first insulating layer and the contact,
wherein a portion of a bottom surface of the word line structure directly contacts the top surface of the contact.

14. The semiconductor structure of claim 13, further comprising:
a third insulating layer on the word line structure and the second insulating layer; and
a plurality of vertical transistors disposed in the first insulating layer, the word line structure, and the third insulating layer,
wherein a top surface of each of the plurality of vertical transistors is lower than a top surface of the third insulating layer.

15. The semiconductor structure of claim 14, wherein a bottom surface of each of the plurality of vertical transistors directly contacts a top surface of each of the plurality of capacitors.

16. The semiconductor structure of claim 14, further comprising:
a plurality of landing pads on the plurality of vertical transistors, respectively, in the third insulating layer, wherein a central portion of a bottom surface of each of the plurality of landing pads directly contacts a top surface of each of the vertical transistors.

17. The semiconductor structure of claim 16, wherein a top surface of each of the landing pads and a topmost surface of the third insulating layer are coplanar.

18. The semiconductor structure of claim 16, wherein each of the plurality of landing pads comprises:
a bottom conductive layer disposed on each of the plurality of vertical transistors; and
a middle conductive layer disposed on the bottom conductive layer, wherein the bottom conductive layer comprises:
a lower portion on the bottom conductive layer and having a lower width; and
an upper portion on the lower portion and having an upper width, wherein the lower width is greater than the upper width.

19. The semiconductor structure of claim 18, further comprising:
a plurality of bit line structures disposed on the plurality of landing pads, respectively.

20. The semiconductor structure of claim 19, wherein a project area of each of the plurality of bit line structures based on the substrate partially overlaps a project area of the upper portion of the middle conductive layer based on the substrate.
